(19) United States
(12) Patent Application Publication
(10) Pub. No.: US 2025/0216787 A1
(43) Pub. Date: Jul. 3, 2025

(54) EDGE BEAD REMOVAL METHOD, SUBSTRATE TREATMENT APPARATUS PERFORMING EDGE BEAD REMOVAL METHOD, AND SUBSTRATE TREATMENT METHOD

(71) Applicant: SEMES CO., LTD., Cheonan-si (KR)

(72) Inventors: Sung Gyu LEE, Suwon-si (KR); Ki Hoon LIM, Bucheon-si (KR); Jun Ho KIM, Seongnam-si (KR); A Rah CHO, Daejeon (KR); Byoung Doo CHOI, Cheonan-si (KR)

(21) Appl. No.: 18/829,177

(22) Filed: Sep. 9, 2024

(30) Foreign Application Priority Data
Dec. 29, 2023 (KR) 10-2023-0196399

(51) Int. Cl. G03F 7/16

(52) U.S. Cl. CPC G03F 7/168; G03F 7/162

(57) ABSTRACT

The present disclosure provides an edge bead removal method in which initial position coordinates of an edge bead removal nozzle are set to both an X-axis value and a Y-axis value, a substrate treatment apparatus performing the same, and a substrate treatment method. The substrate treatment apparatus includes a first unit performing a coating process of forming a film on a substrate, and a controller controlling the first unit. The coating process includes a liquid supply operation of supplying a first liquid to the rotating substrate to form the film on the substrate, and an edge bead removal (EBR) operation of supplying a second liquid to the rotating substrate to remove a portion of the film formed in an edge region of the substrate.

### CROSS-REFERENCE TO RELATED APPLICATION(S)

This application claims benefit of priority to Korean Patent Application No. 10-2023-0196399 filed on Dec. 29, 2023 in the Korean Intellectual Property Office, the disclosure of which is incorporated herein by reference in its entirety.

### BACKGROUND

### 1. Field

The present disclosure relates to an edge bead removal method, a substrate treatment apparatus performing the same, and a substrate treatment method.

### 2. Description of Related Art

In implementing semiconductor devices on a substrate, photolithography technology including exposure and development processes is used. A photosensitive film may be applied by supplying a photosensitive resin composition to a substrate and spinning the substrate. In this case, the photosensitive resin composition may be concentrated at an edge (E) of the substrate by centrifugal force. Accordingly, an edge bead, a small spherical piece of material, may be formed at the edge (E) of the substrate.

Edge beads may be peeled off while a substrate is being transferred, may cause contamination of a facility as particles, and may also cause defocusing during exposure. Accordingly, an edge bead removal (EBR) process may be performed to remove the edge beads after the photosensitive film is coated.

When the above-described EBR process is performed, an initial position of a nozzle may start at (0, Y1) and operations of the EBR process may be performed only through Y-axis motion. When an EBR size (for example, less than 0.5 mm), smaller than an EBR size according to the related art is required, an issue may be likely to occur in EBR nozzle motion control.

### PRIOR ART DOCUMENT

### [Patent Document]

Patent Document 1: Korean Patent Application No. 10-2021-0086878

### SUMMARY

Aspects of the present disclosure provide an edge bead removal method in which initial position coordinates of an edge bead removal nozzle are set to both an X-axis value and a Y-axis value, a substrate treatment apparatus performing the same, and a substrate treatment method.

According to an aspect of the present disclosure, there is provided an edge bead removal method including an operation of positioning, on an edge of a substrate, an edge bead removal nozzle supplying a removal liquid to remove a film formed on the substrate, an operation of setting an X-axis coordinate and a Y-axis coordinate of an initial position of the edge bead removal nozzle, an operation of rotating the substrate while discharging the removal liquid from the edge bead removal nozzle, and an operation of adjusting a region from which the film is removed by changing a value of the Y-axis coordinate, among the coordinates of the initial position.

The edge bead removal method may further include an operation of moving the edge bead removal nozzle to a preset default position.

The operation of adjusting the region may be an operation of adjusting the region from which the film is removed according to a cosine value based on a value of the X-axis coordinate, among the coordinates of the initial position, and a value obtained by changing the value of the Y-axis coordinate, among the coordinates of the initial position.

According to another aspect of the present disclosure, there is provided a substrate treatment apparatus including a first unit performing a coating process of forming a film on a substrate, and a controller controlling the first unit. The coating process may include a liquid supply operation of supplying a first liquid to the rotating substrate to form the film on the substrate, and an edge bead removal (EBR) operation of supplying a second liquid to the rotating substrate to remove a portion of the film formed in an edge region of the substrate. The edge bead removal operation may include an operation of positioning, on an edge of the substrate, an edge bead removal nozzle supplying a removal liquid to remove the film formed on the substrate, an operation of setting an X-axis coordinate and a Y-axis coordinate of an initial position of the edge bead removal nozzle, an operation of rotating the substrate while discharging the removal liquid from the edge bead removal nozzle, and an operation of adjusting a region from which the film is removed by changing a value of the Y-axis coordinate, among the coordinates of the initial position.

The edge bead removal operation may further include an operation of moving the edge bead removal nozzle to a preset default position.

The operation of adjusting the region may be an operation of adjusting the region from which the film is removed according to a cosine value based on a value of the X-axis coordinate, among the coordinates of the initial position, and a value obtained by changing the value of the Y-axis coordinate, among the coordinates of the initial position.

The first unit may include a processing chamber having an internal space, a liquid treatment unit provided in the internal space, the liquid treatment unit performing a liquid treatment process, and an airflow supply unit disposed in an upper portion of the processing chamber to provide downward airflow to the internal space. The liquid treatment unit may include a housing, a treatment container provided in the housing, the treatment container having a treatment space for treating a substrate, a support unit supporting and rotating the substrate in the treatment space, and a liquid supply unit supplying a treatment liquid to the substrate supported by the support unit.

The substrate treatment apparatus may further include a second unit performing a heat treatment process on the substrate.

The substrate treatment apparatus may further include a conveyance unit including a conveyance robot conveying the substrate on which the coating process has been completed.

The conveyance unit may convey the substrate, between the first unit and the second unit.

The first liquid may be a photosensitive liquid, and the second liquid may be a thinner.

According to another aspect of the present disclosure, there is provided a method of treating a substrate, the method including a coating operation of performing a coating process of forming a film on the rotating substrate, and a conveying operation of conveying, to a conveyance robot, the substrate on which the coating process has been completed. The coating operation may include a liquid supply operation of supplying a first liquid to the rotating substrate to form the film on the substrate, and an edge bead removal (EBR) operation of supplying a second liquid to the rotating substrate to remove a portion of the film formed in an edge region of the substrate. The edge bead removal operation may include an operation of positioning, on an edge of the substrate, an edge bead removal nozzle supplying a removal liquid to remove the film formed on the substrate, an operation of setting an X-axis coordinate and a Y-axis coordinate of an initial position of the edge bead removal nozzle, an operation of rotating the substrate while discharging the removal liquid from the edge bead removal nozzle, and an operation of adjusting a region from which the film is removed by changing a value of the Y-axis coordinate, among the coordinates of the initial position.

The edge bead removal operation may further include an operation of moving the edge bead removal nozzle to a preset default position.

The operation of adjusting the region may be an operation of adjusting the region from which the film is removed according to a cosine value based on a value of the X-axis coordinate, among the coordinates of the initial position, and a value obtained by changing the value of the Y-axis coordinate, among the coordinates of the initial position.

The first liquid may be a photosensitive liquid, and the second liquid may be a thinner.

The method may further include performing a heat treatment process on the substrate on which the coating process has been completed.

The conveyance robot may convey the substrate, between a first unit performing the coating process and a second unit performing the heat treatment process.

According to example embodiments of the present disclosure, an edge bead removal region may be precisely adjusted.

### BRIEF DESCRIPTION OF DRAWINGS

The above and other aspects, features, and advantages of the present disclosure will be more clearly understood from the detailed following description, taken in conjunction with the accompanying drawings, in which:

FIG. 1 is a top view of a substrate treatment apparatus;

FIG. 2 is a view of the substrate treatment apparatus of FIG. 1 in a direction of A-A′;

FIG. 3 is a view of the substrate treatment apparatus of FIG. 1 in a direction of B-B′;

FIG. 4 is a schematic cross-sectional view of a structure of a substrate treatment apparatus according to an example embodiment of the present disclosure;

FIG. 5 is a flowchart of a substrate treatment method according to an example embodiment of the present disclosure;

FIG. 6 is a diagram of an edge bead removal method according to an example embodiment of the present disclosure; and

FIG. 7 is a diagram of an operation of an edge bead removal nozzle according to an edge bead removal method according to an example embodiment of the present disclosure.

### DETAILED DESCRIPTION

Hereinafter, preferred example embodiments will be described in detail with reference to accompanying drawings, such that the present disclosure could be easily carried out by those skilled in the art.

In order to clearly describe the present disclosure, irrelevant descriptions are omitted, and the same reference numerals will be used throughout to designate the same or like elements.

In addition, in various example embodiments, components having the same configuration will be described using the same reference numeral only in representative embodiments. In other example embodiments, only components different from those in the representative embodiments will be described.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, operations, operations, elements, components or a combination thereof, but do not preclude the presence or addition of one or more other features, integers, operations, operations, elements, components, and/or groups thereof.

Unless otherwise defined herein, all terms used herein including technical or scientific terms have the same meanings as those generally understood by one of ordinary skill in the art. Terms defined in dictionaries generally used should be construed to have meanings matching contextual meanings in the related art and are not to be construed as having an ideal or excessively formal meaning, unless otherwise defined herein.

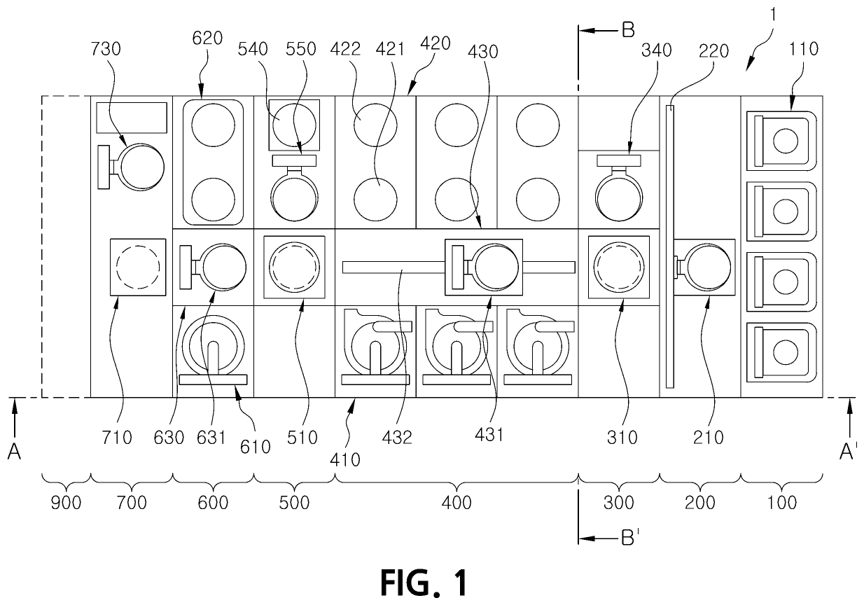

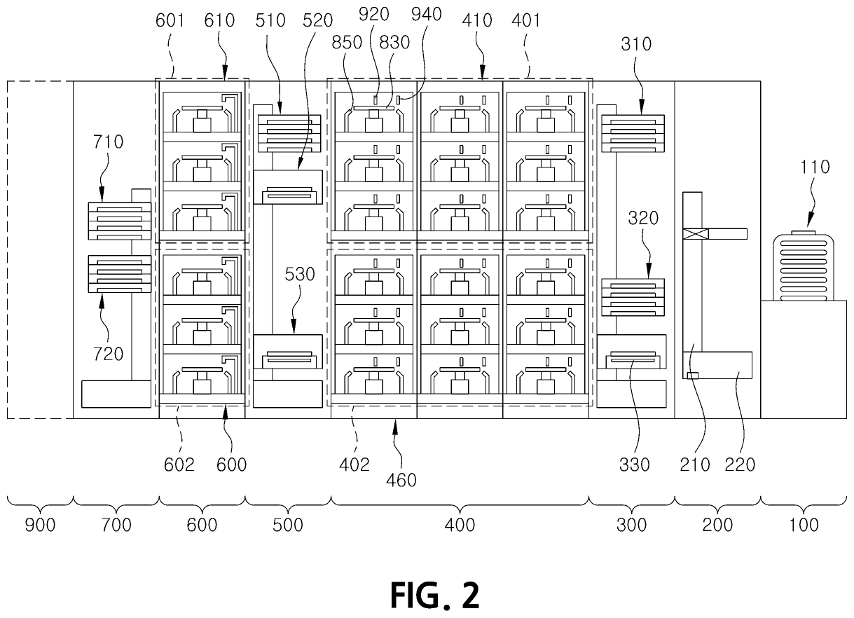

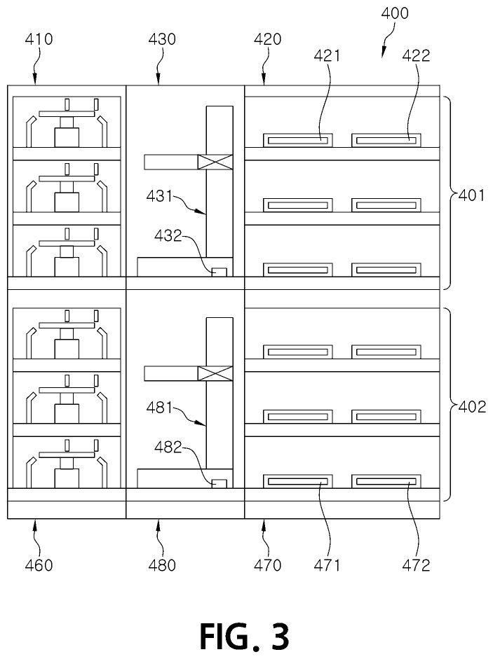

FIG. 1 is a top view of a substrate treatment apparatus. FIG. 2 is a view of the substrate treatment apparatus of FIG. 1 in a direction of A-A′. FIG. 3 is a view of the substrate treatment apparatus of FIG. 1 in a direction of B-B′.

Referring to FIGS. 1 to 3, a substrate treatment facility 1 may include a load port 100, an index module 200, a first buffer module 300, a first process module 400, a second buffer module 500, a second process module 600, and an interface module 700.

The load port 100 may be configured to receive containers 110 in which a substrate S is stored. For example, the containers 110 may be front-opening integrated pods (FOUP). The containers C may be imported from the outside to the load port 100 by an overhead hoist transfer (OHT) or may be exported from the load port 100 to the outside.

The index module 200 may transfer the substrate S, between the containers 110 accommodated in the load port 100 and the first buffer module 300. The index module 200 may include an index robot 210 and an index rail 220. The index robot 210 may move along the index rail 220 to the container 110 accommodated in the load port or to a position adjacent to the first buffer module 300.

The first buffer module 300 may include a first buffer 310, a second buffer 320, a cooling chamber 330, and a first buffer robot 340. The first buffer 310 and the second buffer 320 may temporarily store a substrate transferred from the index module 200 to the first process module 400 or from the first process module 400 to the index module 200.

The first buffer 310 may be disposed to have a height corresponding to that of a coating module 401 of the first process module 400 to be described below. The second buffer 320 and the first cooling chamber 330 may be disposed to have a height corresponding to a development module 402 of the first process module 400 to be described below.

The first buffer robot 340 may transfer the substrate S, between the first buffer 310 and the second buffer 320. The first cooling chamber 330 may be configured to cool the substrate S. The substrate S of the cooling chamber 330 may be carried in or out by the index robot 210 or a development portion robot 481 of the development module 402 to be described below.

The first process module 400 may include a coating module 401 and a development module 402. The coating module 401 may be configured to perform a process of coating a photosensitive liquid such as a photoresist of the substrate S, and a heat treatment process of heating or cooling the substrate S before and after the coating process.

The coating module 401 may include resist coating chambers 410, first bake chambers 420, and a first transfer chamber 430.

The first transfer chamber 430 may transfer the substrate S, between the first buffer module 300, the coating module 401, and the second buffer module 500. The first transfer chamber 430 may include a coating portion robot 431 and a coating portion rail 432. The coating portion robot 431 may move to positions adjacent to the resist coating chambers 410, the first bake chambers 420, the first buffer module 300, and the second buffer module 500, disposed to be adjacent to each other along the coating portion rail 432. The resist coating chambers 410 and the first bake chambers 420 may be disposed along a side surface of the first transfer chamber 430. For example, the resist coating chambers 410 and the first bake chambers 420 may be spaced apart from each other with the first transfer chamber 430 interposed therebetween.

The first baking chamber 420 may perform heat treatment on the substrate S. The first baking chamber 420 may include a cooling plate 421 and a heating plate 422. For example, the first baking chamber 420 may be configured to perform a pre-baking process of removing organic matter or moisture from a surface of the substrate S, or a soft baking process performed after a coating liquid is coated on the substrate S.

The development module 402 may be configured to perform a development process of removing a portion of a photoresist by supplying a developer, and a heat treatment process of heating or cooling the substrate S before and after the development process, so as to form a pattern on the substrate S.

The development module 402 may include development chambers 610, second bake chambers 620, and a second transfer chamber 630.

The second transfer chamber 480 may transfer the substrate S, between the first buffer module 300, the development module 402, and the second buffer module.

The second transfer chamber 480 may include a development portion robot 481 and a development portion rail 482. The development portion robot 481 may move to positions adjacent to the development chambers 460, the second bake chambers 470, the first buffer module 300 and the second buffer module 500, disposed to be adjacent to each other along the development portion rail 482. The development chambers 460 and the second bake chambers 470 may be disposed along a side surface of the second transfer chamber 480. For example, the development chambers 460 and the second bake chambers 470 may be spaced apart from each other with the second transfer chamber 480 interposed therebetween.

The second buffer module 500 may be configured to transfer the substrate S, between the first process module 400 and an exposure pre/post-treatment module 600, or may be configured to perform an edge exposure process and a cooling process on the substrate.

The second buffer module 500 may include a third buffer 510, a second cooling chamber 520, a third cooling chamber 530, an edge exposure chamber 540, and a second buffer robot 550. The third buffer 510, the second cooling chamber 520, and the edge exposure chamber 540 may be disposed to have a height corresponding to that of the coating module 401. The third cooling chamber 530 may be disposed to have a height corresponding to that of the development module 402.

The second cooling chamber 520 and the edge exposure chamber 540 may be configured to perform a subsequent process on the substrate S on which a process has been performed by the coating module 401. For example, the second cooling chamber 520 may be configured to cool the substrate S on which a process has been performed by the coating module 401. The edge exposure chamber 540 may be configured to expose an edge E of the substrate S on which a cooling process has been performed by the second cooling chamber 520.

The third buffer 510 may be configured to temporarily store the substrate S on which a process has been performed by the edge exposure chamber 540 before being transferred to a pre-treatment module 601 to be described below.

The third cooling chamber 530 may be configured to cool the substrate S on which a process has been performed by a post-treatment module 602 to be described below before being transferred to the development module 402.

The exposure pre/post-treatment module 600 may be configured to perform a process of coating a composition for forming a protective film to protect a resist film formed on the substrate S, a process of cleaning the substrate S, or a process of baking the substrate S. The exposure pre/post-treatment module 600 may include an exposure pre-treatment module 601 and an exposure post-treatment module 602.

The interface module 700 may be configured to transfer the substrate S, between the exposure pre/post-treatment module 600 and an exposure apparatus 900. The exposure apparatus 900 may be configured to perform a lithography process. For example, the exposure apparatus 900 may include liquid immersion exposure equipment or extreme ultraviolet (EUV) exposure equipment.

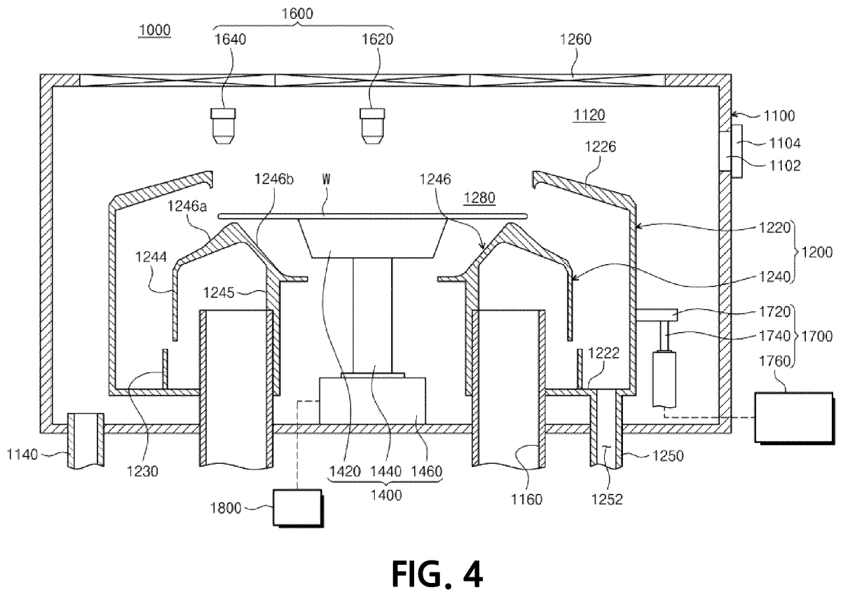

FIG. 4 is a schematic cross-sectional view of a structure of a substrate treatment apparatus according to an example embodiment of the present disclosure.

Referring to FIG. 4, the substrate treatment apparatus may include a housing 1100, a treatment container 1200, a substrate support unit 1400, and a liquid supply unit 1600.

The housing 1100 may have a rectangular cylindrical shape having an internal space 1120. An opening 1102 may be formed in one side of the housing 1100. The opening 1102 may function as a passage through which the substrate W is carried in and out. The opening 1102 may have a door 1104, and the door 1104 may open and close the opening 1102.

The treatment container 1200 may be provided in the internal space 1120 of the housing 1100. The treatment container 1200 may have a treatment space 1280. An upper portion of the treatment space 1280 may be open.

The support unit 1400 may support the substrate W in the treatment space 1280 of the treatment container 1200. The support unit 1400 may include a support plate 1420, a rotating shaft 1440, and a driver 1460. The support plate 1420 may have a circular upper surface. The support plate 1420 may have a diameter smaller than that of the substrate W. The support plate 1420 may support the substrate W using vacuum pressure. Optionally, the support plate 1420 may have a mechanical clamping structure to support the substrate W. The rotating shaft 1440 may be coupled to a central portion of a bottom surface of the support plate 1420, and the rotating shaft 1440 may include the driver 1460, providing rotating force to the rotating shaft 1440. The driver 1460 may be a motor.

The liquid supply unit 1600 may supply a liquid onto the substrate W. The liquid supply unit 1600 may supply various types of liquids onto the substrate W. According to an example, the liquid supply unit 1600 may supply a coating liquid, an edge bead removal liquid, or the like onto the substrate W.

The liquid supply unit 1600 may include a film formation unit and an edge bead removal unit. The film formation unit may include a first nozzle 1620 supplying a first liquid L1 onto the substrate W, a guide member (not illustrated), and an arm (not illustrated). The first liquid L1 may be a coating liquid such as a photoresist. The guide member and the arm may move the first nozzle 1620 to a process position and a standby position. Here, the process position may be defined as a position in which the first nozzle 1620 opposes the substrate W, and the standby position may be defined as a position outside of the process position. The guide member may include a guide rail (not illustrated), moving the arm in a horizontal direction. The guide rail may be positioned on one side of the treatment container 1200. A length direction of the guide rail may be a horizontal direction. For example, the length direction of the guide rail may be parallel to a first direction. The guide rail may have an arm. The arm may be moved by a linear motor (not illustrated) provided on the inside of the guide rail. A length direction of the arm may be perpendicular to the guide rail, when viewed above. One end of the arm may be mounted on the guide rail. The first nozzle 1620 may be installed on a bottom surface of the other end of the arm. Optionally, the arm may be rotated in a state of being coupled to a rotating shaft having a length direction, a third direction.

The edge bead removal unit may perform an edge bead removing (EBR) process. The edge bead removal unit may remove a coating liquid film formed in an edge region of the substrate W, included in the film formed on the substrate W. The edge bead removal unit may expose an edge portion of the substrate W from the coating liquid film. The edge bead removal unit may include a second nozzle 1640 supplying a second liquid L2, a guide member (not illustrated), an arm (not illustrated), and a cleaning member (not illustrated). The guide member and the arm of the edge bead removal unit may respectively have shapes the same as those of the guide member and the arm of the film formation unit. The guide member and the arm of the edge bead removal unit may be driven independently of the film formation unit. Detailed descriptions of the guide member and the arm of the edge bead removal unit will be omitted. The liquid supply unit 1600 and the edge bead removal unit may be first units, performing a coating process under control of the controller 1800.

The second nozzle 1640 may discharge the second liquid L2 onto a liquid film coated on the substrate W. The second nozzle 1640 may supply the second liquid L2 to the edge portion of the substrate W. The second liquid L2 may include an edge bead removal liquid. For example, the first liquid L1 may be an organic material, and the second liquid L2 may be a liquid which may react with the organic material. The first liquid L1 may be a photosensitive liquid such as a photoresist, and the second liquid L2 may be a thinner.

A fan filter unit 1260, supplying downward airflow to the internal space, may be disposed on an upper wall of the housing 1100. The fan filter unit 1260 may have a fan introducing external air into the internal space, and a filter filtering external air.

In the housing 1100, an outer exhaust pipe 1140 exhausting airflow supplied to a space between the treatment container 1200 and the housing 1100, and an inner exhaust pipe 1160 exhausting airflow supplied to an internal space of the treatment container 1200 may be connected to the outside of the treatment container 1100. The outer exhaust pipe 1140 and the inner exhaust pipe 1160 may have a pressure adjustment member (not illustrated), so as to forcibly suction airflow in the exhaust space. The pressure adjustment member may be a pump.

The treatment container 1200 may include an outer cup 1220 and an inner cup 1240.

The outer cup 1220 may surround the support unit 1400 and the substrate W supported by the support unit 1400. The outer cup 1220 may have a bottom wall 1222, a side wall 1224, and an upper wall 1226. The inside of the outer cup 1220 may be provided as the treatment space 1280 described above.

The bottom wall 1222 may have a circular shape, and may have an opening at the center thereof. The side wall 1224 may extend upwardly from an outer end of the bottom wall 1222. The side wall 1224 may have a ring shape, and may be perpendicular to the bottom wall 1222. For example, the side wall 1224 may extend to have a height the same as that of an upper surface of the support plate 1420, or to have a height slightly lower than that of the upper surface of the support plate 1420. The upper wall 1226 may have a ring shape, and may have an opening at the center thereof. The upper wall 1226 may be upwardly inclined from an upper end of the side wall 1224 toward a central axis of the outer cup 1220.

The inner cup 1240 may be positioned on the inside of the outer cup 1220. The inner cup 1240 may have an inner wall 1242, an outer wall 1244, and an upper wall 1246. The inner wall 1242 may have a through-hole in a vertical direction. The inner wall 1242 may be disposed to surround the driver 1460. The inner wall 1242 may minimize exposure of the driver 1460 to airflow in the treatment space 1280. The rotating shaft 1440 and/or the driver 1460 of the support unit 1400 may extend in the vertical direction through the through-hole. A lower end of the inner wall 1242 may be positioned on the bottom wall 1222 of the outer cup 1220. The outer wall 1244 may be disposed to be spaced apart from the inner wall 1242 and to surround the inner wall 1242. The outer wall 1244 may be positioned to be spaced apart from the side wall 1224 of the outer cup 1220. The inner wall 1242 may be disposed to be upwardly spaced apart from the bottom wall 1222 of the outer cup 1220. The upper wall 1246 may connect an upper end of the outer wall 1244 and an upper end of the inner wall 1242 to each other. The upper wall 1246 may have a ring shape, and may be disposed to surround the support plate 1420. According to an example, the upper wall 1246 may have an upwardly convex shape. The upper wall 1246 may have an outer upper wall 1246a upwardly inclined from the upper end of the outer wall 1244 toward the rotating shaft 1440, and an inner upper wall 1246b downwardly inclined from the outer upper wall 1246a to the upper end of the inner wall 1242. The support plate 1420 may be positioned in a space surrounded by the inner upper wall 1246b. According to an example, a peak of the upper wall 1226 may be positioned further outwardly than the support plate 1420, and may be positioned further inwardly than an end of the substrate W supported by the support unit 1400.

A gas-liquid separator 1230 may be provided in the treatment space 1280 of the treatment container 1200. The gas-liquid separator 1230 may extend upwardly from the bottom wall 1222 of the outer cup 1220. The gas-liquid separator 1230 may have a ring shape. When viewed from above, the gas-liquid separator 1230 may be positioned between the sidewall 1224 of the outer cup 1220 and the outer wall 1244 of the inner cup 1240. Optionally, the gas-liquid separator 1230 may be positioned to overlap the outer wall 1244 of the inner cup 1240, or may be positioned further inwardly than the outer wall 1244 of the inner cup 1240. According to an example, an upper end of the gas-liquid separator 1230 may be positioned to be lower than a lower end of the outer wall 1244 of the inner cup 1240.

The inner exhaust pipe 1160 may be connected to the bottom wall 1222 of the outer cup 1220. The inner exhaust pipe 1160 may exhaust airflow introduced into the internal space 1280 of the treatment container 1200. The inner exhaust pipe 1160 may be positioned to be closer to the inner cup 1240 than to the outer cup 1220. When viewed from above, the inner exhaust pipe 1160 may overlap the inner cup 1240.

A discharge pipe 1250, discharging a treatment liquid, may be connected to the bottom wall 1222 of the outer cup 1220. The discharge pipe 1250 may discharge a treatment liquid, introduced into a space between the sidewall 1224 of the outer cup 1220 and the outer wall 1244 of the inner cup 1240, to the outside of the treatment container 1200. According to an example, a space between the sidewall 1224 of the outer cup 1220 and the gas-liquid separator 1230 may be provided as a discharge space for discharging the treatment liquid, and the discharge pipe 1250 may be provided to discharge the treatment liquid from the discharge space. Airflow, flowing into the space between the sidewall 1224 of the outer cup 1220 and the outer wall 1244 of the inner cup 1240, may be introduced into a space surrounded by the sidewall 1224 and the bottom wall 1222 of the outer cup 1220, and the gas-liquid separator 1230, and may be exhausted through the inner exhaust pipe 1160. In such a process, the treatment liquid contained in the airflow may be discharged to the outside of the treatment container 1200 through the discharge pipe 1250, and the airflow may be exhausted by an exhaust unit (not illustrated) of the treatment container 1200.

One or more discharge pipes 1250 may be provided. When a plurality of discharge pipes 1250 are provided, the plurality of discharge pipes 1250 may be provided in a circumferential direction of the inner cup 1240.

The substrate treatment apparatus 1000 may include a lifting unit 1700. The lifting unit 1700 may adjust relative heights of the treatment container 1200 and the support unit 1400. The lifting unit 1700 may move the treatment container 1200 in the vertical direction. Specifically, the lifting unit 1700 may adjust relative heights of the support plate 1420 and the outer cup 1220. For example, the lifting unit 1700 may lift and lower the outer cup 1220 in the vertical direction. For example, when the substrate W is loaded on the support plate 1420 or the substrate W is unloaded from the support plate 1420, the support plate 1420 may be positioned to have a height higher than that of an upper end of the outer cup 1220, thereby preventing a conveyance robot 352 conveying the substrate W from interfering with the outer cup 1220. In addition, when a process is performed, the support plate 1420 may be positioned to have a height lower than that of the upper end of the outer cup 1220, such that the substrate W may be positioned in the treatment space.

The lifting unit 1700 may include a bracket 1720, a moving shaft 1740, and a driver 1760. The bracket 1720 may connect the treatment container 1200 and the moving shaft 1740 to each other. The bracket 1720 may be fixed to the outer cup 1220 of the treatment container 1200. The bracket 1720 may be fixedly installed on the sidewall 1224 of the outer cup 1220. A length direction of the moving shaft 1740 may be the vertical direction. An upper end of the moving shaft 1740 may be fixedly coupled to the bracket 1720. The moving shaft 1740 may receive power from the driver 1760. The moving shaft 1740 may be moved from the driver 1760 in the vertical direction, and the treatment container 1200 may be moved in a liftable manner, together with the moving shaft 1740. The driver 1760 may provide power to the moving shaft 1740. The driver 1760 may provide power, such that the moving shaft 1740 may reciprocate linearly or move in a liftable manner. For example, the driver 1760 may be a cylinder or a motor.

The controller 1800 may control an overall operation of the substrate treatment apparatus 1000. The controller 1800 may control respective components of the substrate treatment apparatus 1000. The controller 1800 may include a central processing unit (CPU), a read only memory (ROM), and a random access memory (RAM). The CPU may execute desired processing according to various recipes stored in memory regions thereof. In the recipe, process time, process pressure, progress temperature, various gas flow rates, and the like, control information pieces of the apparatus for a process condition, may be input. A recipe indicating the above-described programs or processing conditions may be stored in a hard disk or a semiconductor memory. In addition, the recipe may be set at a predetermined position of a memory region in a state of being accommodated in a computer-readable storage medium such as a CD-ROM or a DVD.

The controller 1800 may control a rotation speed of the substrate W by controlling the support unit 1400. In addition, the controller 1800 may control the above-described coating process. The above-described coating process may include a liquid supply operation of supplying a first liquid to the rotating substrate W to form a film on the substrate W, and an edge bead removal (EBR) operation of removing a portion of the film formed in an edge region of the substrate W by supplying a second liquid to the rotating substrate W.

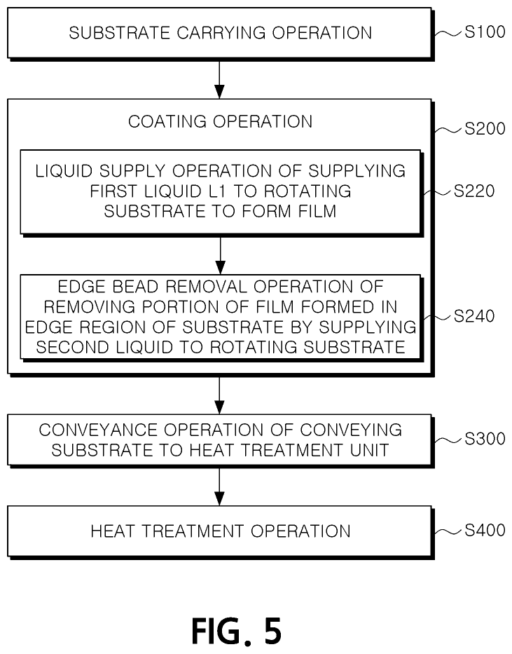

FIG. 5 is a flowchart of a substrate treatment method according to an example embodiment of the present disclosure. Referring to FIG. 5 together with FIG. 4, the substrate treatment method may include a substrate carrying operation S100, a coating operation S200, a conveyance operation S300, and a heat treatment operation S400.

A substrate W may be carried into a housing 1100 of a substrate treatment apparatus 1000 (S100). The substrate W may be introduced into the housing 1100 by a conveyance robot 352. In this case, a door 1104 may be opened. The substrate W may be carried into the housing 1100 through an opening 1102 in a state of being mounted on a hand 354 of the robot 352, and may be mounted on a support unit 1400.

In the coating operation S200, a coating process of forming a film on the rotating substrate W may be performed. The coating operation S200 may include a liquid supply operation S220 of supplying a first liquid L1 to the rotating substrate W to form a film on the substrate, and an edge bead removal operation S240 of removing a portion of the film formed in an edge region of the substrate W by supplying a second liquid L2 to the rotating substrate W. A controller 1800 may stop rotation when the conveyance robot 352 reaches a preset position, and the conveyance robot 352 may pick up the substrate W and convey the substrate W to the heat treatment chamber 320. In this case, the preset position may refer to a position in which the conveyance robot 352 is positioned in front of the door 1104 of the substrate treatment apparatus 1000 performing the coating process. That is, the controller 1800 may rotate the substrate W at a preset speed until the conveyance robot 352 is positioned in front of the door 1104 with respect to the substrate W on which the coating process has been completed, and may stop rotation of the substrate W when the conveyance robot 352 is positioned in front of the door 1104. Thereafter, the conveyance robot 352 may be introduced into the housing 1100 through the opening 1102 to pick up the stopped substrate W. The conveyance robot 352 may convey the substrate W, on which the coating process has been completed, to a chamber in which a subsequent treatment process is performed (a conveyance operation S300). For example, the subsequent treatment process may be a heat treatment process. In this case, the conveyance robot 352 may convey the substrate W to the heat treatment chamber 320. The substrate W, conveyed to the heat treatment chamber 320, may be subjected to the heat treatment process in which a coating liquid film on the substrate W is stabilized (the heat treatment operation S400).

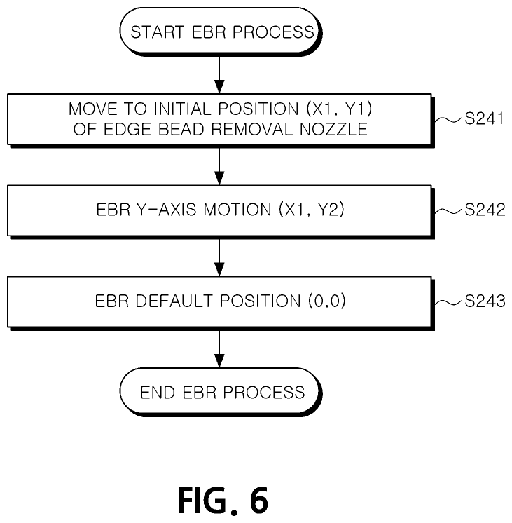

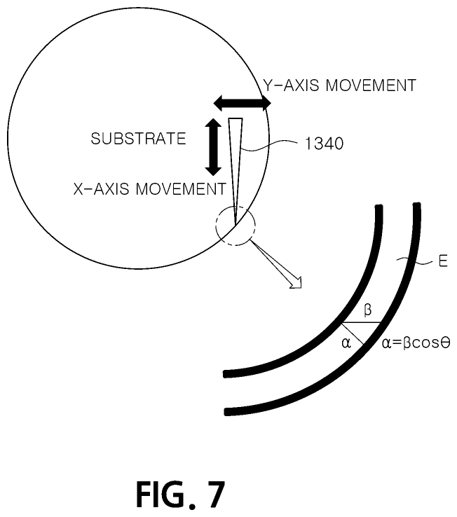

FIG. 6 is a diagram of an edge bead removal method according to an example embodiment of the present disclosure. FIG. 7 is a diagram of an operation of an edge bead removal nozzle according to an edge bead removal method according to an example embodiment of the present disclosure.

Referring to FIG. 6, after the above-described liquid supply operation, in the edge bead removal operation, an initial position of an edge bead removal nozzle 1340 may be on an edge of the substrate under control of the controller 1800 (S241). In this case, the initial position of the edge bead removal nozzle 1340 may use both an X-axis value and a Y-axis value (X1 and Y1). The edge bead removal nozzle 1340 may be configured to spray an EBR solution onto an edge E of the substrate. The EBR solution may include a thinner composition. For example, the thinner composition may be a solution having solubility in a resist coating film. Accordingly, an edge bead, formed on an edge E of the resist coating film, may be dissolved in the thinner composition and removed. Thereafter, while a removal liquid is discharged from the edge bead removal nozzle 1340, the substrate may be rotated. When the EBR solution is sprayed onto the edge bead, fumes including particulates including an EBR solution component, particulates including a coating film component of an edge bead, and particulates including a product component caused by a chemical reaction between the EBR solution and the edge bead may occur. The fumes may cause a decrease in pattern reliability in a semiconductor process of forming a fine pattern, or a facility malfunction. The edge bead removal nozzle 1340 may be configured to obliquely spray an EBR solution onto an upper surface of the substrate.

A value of a Y-axis coordinate, among coordinates of the initial position, may be changed (Y1->Y2), thereby adjusting a region from which the film is removed (S242).

Referring to FIG. 7, the region from which the film is removed may be adjusted according to a cosine value based on a value of an X-axis coordinate, among the coordinates of the initial position, and a value obtained by changing the value of the Y-axis coordinate, among the coordinates of the initial position, as illustrated in the following equation.

$$α = β cos θ \qquad ( Equation )$$

Here, α may refer to a width of the region from which the film is removed, β may refer to a Y-axis movement distance based on the value obtained by changing the value of the Y-axis coordinate, among the coordinates of the initial position, and θ may refer to an angle based on the X-axis coordinate value and Y-axis coordinate value of the edge bead removal nozzle 1340.

Even when the same distance is moved by a cosine component described above, adjustment of a EBR region, smaller than an EBR region according to the related art, may be derived. When precise EBR size response is required, a margin for EBR nozzle motion may be secured.

Thereafter, the edge bead removal nozzle 1340 may be moved to predetermined default positions (X0, Y0) (S243).

As described above, according to the present disclosure, an edge bead removal region may be precisely adjusted.

While example embodiments have been shown and described above, it will be apparent to those skilled in the art that modifications and variations could be made without departing from the scope of the present disclosure as defined by the appended claims.

What is claimed is:

1. An edge bead removal method comprising:
an operation of positioning, on an edge of a substrate, an edge bead removal nozzle supplying a removal liquid to remove a film formed on the substrate;
an operation of setting an X-axis coordinate and a Y-axis coordinate of an initial position of the edge bead removal nozzle;
an operation of rotating the substrate while discharging the removal liquid from the edge bead removal nozzle; and
an operation of adjusting a region from which the film is removed by changing a value of the Y-axis coordinate, among the coordinates of the initial position.

2. The edge bead removal method of claim 1, further comprising:
an operation of moving the edge bead removal nozzle to a preset default position.

3. The edge bead removal method of claim 1, wherein the operation of adjusting the region is an operation of adjusting the region from which the film is removed according to a cosine value based on a value of the X-axis coordinate, among the coordinates of the initial position, and a value obtained by changing the value of the Y-axis coordinate, among the coordinates of the initial position.

4. A substrate treatment apparatus comprising:
a first unit performing a coating process of forming a film on a substrate; and
a controller controlling the first unit,
wherein the coating process includes:
a liquid supply operation of supplying a first liquid to the rotating substrate to form the film on the substrate; and
an edge bead removal (EBR) operation of supplying a second liquid to the rotating substrate to remove a portion of the film formed in an edge region of the substrate, and
the edge bead removal operation includes:
an operation of positioning, on an edge of the substrate, an edge bead removal nozzle supplying a removal liquid to remove the film formed on the substrate;
an operation of setting an X-axis coordinate and a Y-axis coordinate of an initial position of the edge bead removal nozzle;
an operation of rotating the substrate while discharging the removal liquid from the edge bead removal nozzle; and
an operation of adjusting a region from which the film is removed by changing a value of the Y-axis coordinate, among the coordinates of the initial position.

5. The substrate treatment apparatus of claim 4, wherein the edge bead removal operation further includes an operation of moving the edge bead removal nozzle to a preset default position.

6. The substrate treatment apparatus of claim 4, wherein the operation of adjusting the region is an operation of adjusting the region from which the film is removed according to a cosine value based on a value of the X-axis coordinate, among the coordinates of the initial position, and a value obtained by changing the value of the Y-axis coordinate, among the coordinates of the initial position.

7. The substrate treatment apparatus of claim 4, wherein
the first unit includes:
a processing chamber having an internal space;
a liquid treatment unit provided in the internal space, the liquid treatment unit performing a liquid treatment process; and
an airflow supply unit disposed in an upper portion of the processing chamber to provide downward airflow to the internal space, and
the liquid treatment unit includes:
a housing;
a treatment container provided in the housing, the treatment container having a treatment space for treating a substrate;
a support unit supporting and rotating the substrate in the treatment space; and
a liquid supply unit supplying a treatment liquid to the substrate supported by the support unit.

8. The substrate treatment apparatus of claim 4, further comprising:
a second unit performing a heat treatment process on the substrate.

9. The substrate treatment apparatus of claim 8, further comprising:
a conveyance unit including a conveyance robot conveying the substrate on which the coating process has been completed.

10. The substrate treatment apparatus of claim 9, wherein the conveyance unit conveys the substrate, between the first unit and the second unit.

11. The substrate treatment apparatus of claim 4, wherein
the first liquid is a photosensitive liquid, and
the second liquid is a thinner.

12. A method of treating a substrate, the method comprising:
a coating operation of performing a coating process of forming a film on the rotating substrate; and
a conveying operation of conveying, to a conveyance robot, the substrate on which the coating process has been completed,
wherein the coating operation includes:
a liquid supply operation of supplying a first liquid to the rotating substrate to form the film on the substrate;
an edge bead removal (EBR) operation of supplying a second liquid to the rotating substrate to remove a portion of the film formed in an edge region of the substrate,
the edge bead removal operation includes:
an operation of positioning, on an edge of the substrate, an edge bead removal nozzle supplying a removal liquid to remove the film formed on the substrate;
an operation of setting an X-axis coordinate and a Y-axis coordinate of an initial position of the edge bead removal nozzle;
an operation of rotating the substrate while discharging the removal liquid from the edge bead removal nozzle; and
an operation of adjusting a region from which the film is removed by changing a value of the Y-axis coordinate, among the coordinates of the initial position.

13. The method of claim 12, wherein the edge bead removal operation further includes an operation of moving the edge bead removal nozzle to a preset default position.

14. The method of claim 12, wherein the operation of adjusting the region is an operation of adjusting the region from which the film is removed according to a cosine value based on a value of the X-axis coordinate, among the coordinates of the initial position, and a value obtained by changing the value of the Y-axis coordinate, among the coordinates of the initial position.

15. The method of claim 12, wherein
the first liquid is a photosensitive liquid, and
the second liquid is a thinner.

16. The method of claim 12, further comprising:
performing a heat treatment process on the substrate on which the coating process has been completed.

17. The method of claim 16, wherein the conveyance robot conveys the substrate, between a first unit performing the coating process and a second unit performing the heat treatment process.
